(19) United States
(12) Patent Application Publication
(10) Pub. No.: US 2026/0293572 A1
(43) Pub. Date: Sep. 24, 2026

(54) SUBSTRATE PROCESSING APPARATUS AND SUBSTRATE PROCESSING METHOD

(71) Applicant: SHIBAURA MECHATRONICS CORPORATION, Kanagawa (JP)

(72) Inventors: Rie TESHIMA, Kanagawa (JP); Jun MATSUSHITA, Kanagawa (JP); Hikaru HOSHINO, Kanagawa (JP); Kengo KAMEI, Kanagawa (JP)

(21) Appl. No.: 19/570,598

(22) Filed: Mar. 18, 2026

(30) Foreign Application Priority Data
Mar. 21, 2025 (JP) 2025-046695

(51) Int. Cl. H10P 72/00; H10P 72/76

(52) U.S. Cl. CPC H10P 72/0414; H10P 72/0408; H10P 72/0436; H10P 72/7618; H10P 72/7612

(57) ABSTRACT

According to one embodiment of the present disclosure, a substrate processing apparatus includes: a processing liquid supply unit that supplies a processing liquid to a substrate; a heating unit that irradiates light onto the substrate, thereby heating the substrate; a cover body including an opposing surface that faces the substrate held by a rotary holding unit, and transmitting the light irradiated by the heating unit; and a control device that controls the processing liquid supply unit and the heating unit. The control device is configured to supply the processing liquid to the rotating substrate, thereby processing the substrate, and perform a first drying process that irradiates the light onto the substrate held by the rotary holding unit to heat the substrate, thereby drying the opposing surface of the cover body.

### CROSS REFERENCES TO RELATED APPLICATIONS

This application is based on and claims priority from Japanese Patent Application No. 2025-046695, filed on Mar. 21, 2025, with the Japan Patent Office, the disclosure of which is incorporated herein in its entirety by reference.

### TECHNICAL FIELD

The present disclosure relates to a substrate processing apparatus and a substrate processing method.

### BACKGROUND

A single-wafer type substrate processing apparatus is known in which, while rotating a substrate such as a semiconductor wafer, a processing liquid is supplied to the substrate, and processing such as etching or resist removal is performed. In the substrate processing apparatus, the substrate or the processing liquid thereon is heated by a heating unit including, for example, a heater during the processing, thereby increasing the temperature of the processing liquid, and consequently, improving processing efficiency. See, for example, Japanese Patent Laid-Open Publication No. 2015-211201.

### SUMMARY

In the substrate processing apparatus, for example, a cover body is provided between the substrate held by a rotary holding unit and the heating unit that heats the processing liquid, to cover the heating unit, and the cover body has an opposing surface that faces the substrate. When the substrate is processed by the processing liquid, droplets may adhere to the opposing surface of the cover body.

When a heating is performed by the heating unit through a light irradiation, the light normally passes through the cover body and is irradiated onto the substrate, and as a result, there may be a case where the cover body itself is not heated. When the cover body is not heated, the droplets adhering to the opposing surface remain on the opposing surface. As a result, there is concern that the residual droplets may fall onto the substrate to contaminate the substrate.

An embodiment of the present disclosure has been proposed to solve the problems above, and provides a substrate processing apparatus and a substrate processing method, which may suppress the contamination of the substrate.

According to an embodiment of the present disclosure, a substrate processing apparatus includes: a rotary holding unit that holds and rotates a substrate; a processing liquid supply unit that supplies a processing liquid to the substrate that is rotating while being held by the rotary holding unit; a heating unit that irradiates light onto the substrate held by the rotary holding unit, thereby heating the substrate; a cover body including an opposing surface that faces the substrate held by the rotary holding unit, provided between the substrate held by the rotary holding unit and the heating unit, and transmitting the light irradiated by the heating unit; and a control device that controls the rotary holding unit, the processing liquid supply unit, and the heating unit. The control device is configured to supply the processing liquid to the substrate that is rotating by the rotary holding unit, thereby processing the substrate, and perform a first drying process that irradiates the light onto the substrate held by the rotary holding unit to heat the substrate, thereby drying the opposing surface of the cover body.

According to another embodiment of the present disclosure, a substrate processing method includes: holding and rotating a substrate by a rotary holding unit; supplying a processing liquid to the rotating substrate, thereby processing the substrate; and drying a cover body provided between the substrate held by the rotary holding unit and a heating unit that heats the substrate by irradiating light onto the substrate. The cover body transmits the light irradiated by the heating unit, and in the drying the cover body, the heating unit irradiates the light onto the substrate to heat the substrate, thereby drying the opposing surface of the cover body that faces the substrate held by the rotary holding unit.

According to an embodiment of the present disclosure, it is possible to suppress the contamination of a substrate.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a partial axial cross-sectional view illustrating a state where a substrate is carried in and out, in a substrate processing apparatus, according to an embodiment.

FIG. 2 is a partial axial cross-sectional view illustrating a state where a processing liquid is supplied, in the substrate processing apparatus of FIG. 1.

FIG. 3 is a partial axial cross-sectional view illustrating a state where a rinse liquid is supplied, in the substrate processing apparatus of FIG. 1.

FIG. 4 is a partial axial cross-sectional view illustrating a state where a cover body cleaning process is performed, in the substrate processing apparatus of FIG. 1.

FIG. 5 is a partial axial cross-sectional view illustrating a state where a second drying process is performed, in the substrate processing apparatus of FIG. 1.

FIG. 6 is a block diagram illustrating a control device of the substrate processing apparatus of FIG. 1.

FIG. 7 is a partial axial cross-sectional view illustrating a state where a first drying process is performed, in the substrate processing apparatus of FIG. 1.

FIG. 8 is a flowchart illustrating the sequence of an etching process, according to an embodiment.

FIG. 9 is a flowchart illustrating the sequence of a maintenance process of a cover body, according to an embodiment.

### DESCRIPTION OF EMBODIMENTS

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

### Embodiment

Hereinafter, an embodiment of the present disclosure will be described with reference to the drawings. The present disclosure is not limited to the embodiment described herein below. Further, in the respective drawings, thicknesses, dimensions, positional relationships, ratios, or shapes may be emphasized to facilitate the understanding of the invention, and the present disclosure is not limited to the emphasized features.

### Overview

The substrates used in the present embodiment include a substrate Wp to be processed with a processing liquid Lp and a substrate Wd to be carried in when a maintenance process of a cover body 63, which will be described herein later, is performed. The substrate Wp is a substrate that becomes a product, and is an example of a first substrate. The substrate Wp that becomes a product is, for example, a disk-shaped silicon wafer with a silicon nitride film and a silicon oxide film formed on a processing target surface thereof, which is a surface to be processed. The substrate Wd is a dummy substrate, and is an example of a second substrate. The dummy substrate Wd is, for example, a disk-shaped silicon wafer, which has the same diameter as the substrate Wp and includes no film formed thereon. Hereinafter, when the substrate Wp and the substrate Wd are not discriminated, they will be collectively referred to as a substrate W.

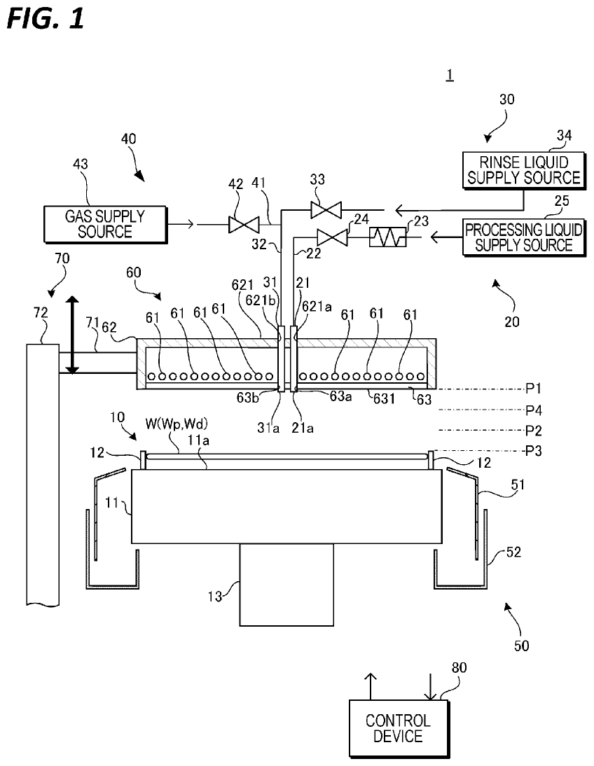

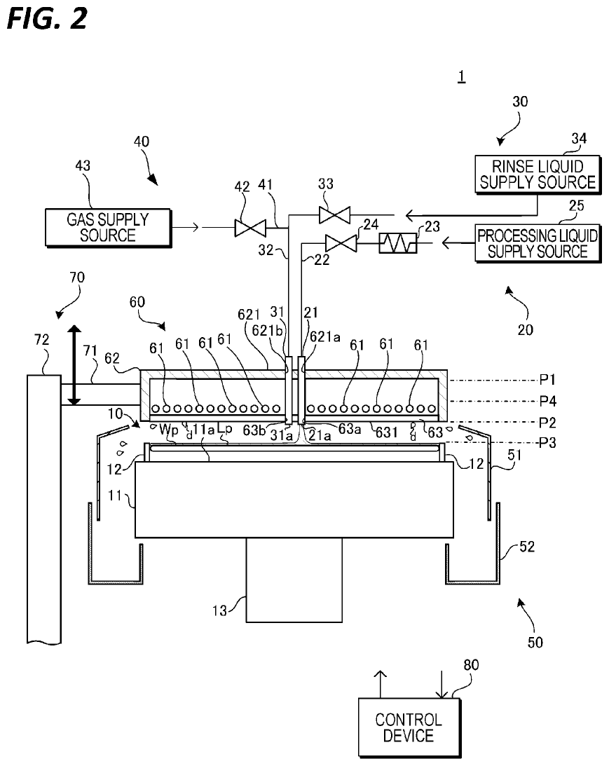

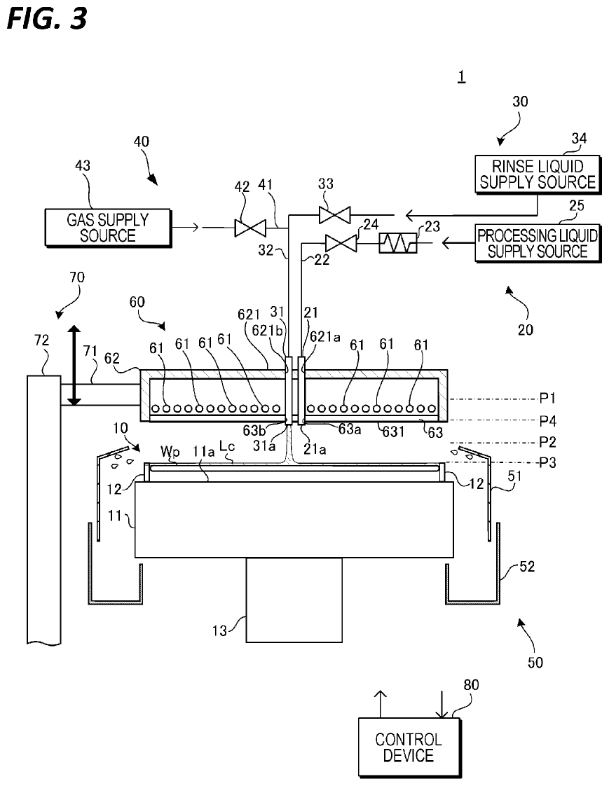

As illustrated in FIG. 1, a substrate processing apparatus 1 processes the substrate Wp by supplying a processing liquid Lp from a processing liquid supply unit 20 to the substrate Wp while rotating the substrate Wp held in a rotary holding unit 10. As illustrated in FIG. 2, the substrate processing apparatus 1 of the present embodiment is a single-sheet type apparatus that performs an etching process by supplying the processing liquid Lp having etching capability to the rotating substrate Wp. Further, in the present embodiment, as illustrated in FIG. 3, a rinse process is performed to supply a rinse liquid Lc from a rinse liquid supply unit 30 to the substrate W before and after the supply of the processing liquid Lp.

The substrate processing apparatus 1 according to an embodiment of the present disclosure includes a heating unit 60 provided with a light emitting element 61. The light emitting element 61 is a light emitting diode (LED) that irradiates light having a wavelength absorbed by the substrate W so as to heat the substrate W itself. Further, the substrate processing apparatus 1 includes a cover body 63 having an opposing surface 63 that faces the substrate W and covers the heating unit 60. The cover body 63 transmits light emitted from the light emitting element 61, and is not heated by the light. The heating unit 60 heats the substrate W by irradiating the light from the light emitting element 61 onto the substrate W through the cover body 63.

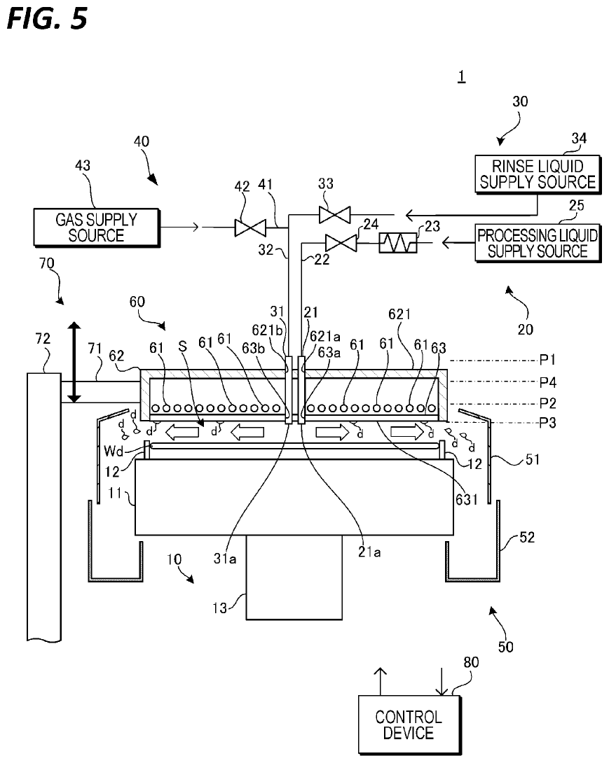

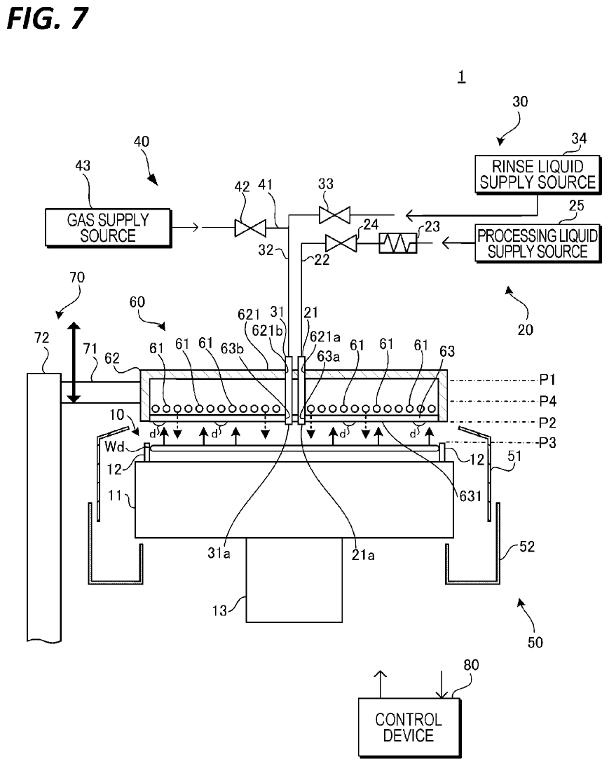

The substrate processing apparatus 1 of the present embodiment performs a maintenance process of the cover body 63 to remove droplets “d” that adhere to the opposing surface 631 of the cover body 63 during the etching process and the rinse process, and contain the processing liquid Lp or the rinse liquid Lc (see, e.g., FIGS. 5 and 7). In the maintenance process of the cover body 63, the opposing surface 631 of the cover body 63 is cleaned and dried. In the maintenance process of the cover body 63, the dummy substrate Wd is used, instead of the substrate Wp that becomes a product.

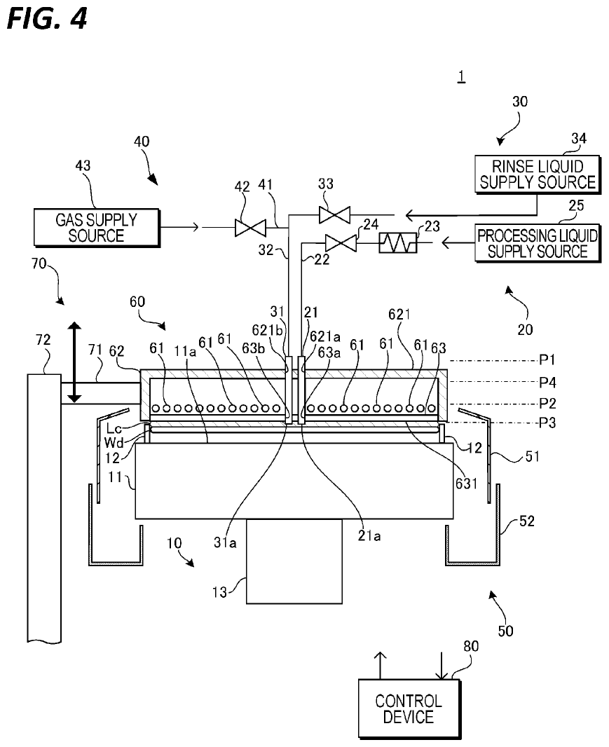

The maintenance process of the cover body 63 includes a cover body cleaning process, a first drying process, and a second drying process. The cover body cleaning process is a process that brings the opposing surface 631 into contact with the rinse liquid Lc supplied to the substrate Wd, thereby washing away the droplets d adhering to the opposing surface 631 and containing the processing liquid Lp (see, e.g., FIG. 4). The first drying process is a process that irradiates the substrate Wd with the light from the light emitting element 61 to heat the substrate Wd, and heats the droplets d adhering to the opposing surface 631 of the cover body 63 by radiant heat generated from the heated substrate Wd, thereby drying the opposing surface 631 (see, e.g., FIG. 7). Here, heating the droplets d includes directly heating the droplets d adhering to the opposing surface 631 by the radiant heat generated from the heated substrate Wd, as well as heating the opposing surface 631 by the radiant heat generated from the heated substrate Wd, and heating the droplets d by the heated opposing surface 631. The second drying process is a process that supplies a gas into a space S formed between the substrate Wd and the opposing surface 631 of the cover body 63 to blow the droplets d adhering to the opposing surface 631 of the cover body 63 outward, thereby drying the opposing surface 631 (see, e.g., FIG. 5).

In the first drying process and the second drying process, the droplets d may remain adhering to the opposing surface 631 after the completion of the maintenance process of the cover body 63, as long as the droplets d adhering to the opposing surface 631 may be removed to a degree that does not contaminate the substrate Wp. Drying the opposing surface 631 indicates reducing the droplets d adhering to the opposing surface 631, as compared to those before the first drying process and the second drying process are performed.

In the present embodiment, the processing liquid Lp is, for example, an aqueous solution containing phosphoric acid (hereinafter, referred to as a phosphoric acid solution). The concentration of phosphoric acid in the processing liquid Lp is, for example, 85 wt % to 94 wt %. The rinse liquid Lc is, for example, pure water (H₂O).

### Configuration

As illustrated in FIG. 1, the substrate processing apparatus 1 includes the rotary holding unit 10, the processing liquid supply unit 20, the rinse liquid supply unit 30, a gas supply unit 40, a liquid receiving unit 50, a heating unit 60, a lifting mechanism 70, and a control device 80.

### (Rotary Holding Unit)

The rotary holding unit 10 holds and rotates the substrate W. As illustrated in FIG. 1, the rotary holding unit 10 includes a rotary table 11, a chuck pin 12, and a drive unit 13. The rotary table 11 is a cylindrical member, and one end thereof is closed by a lid unit 11a. The lid unit 11a is a circular surface having a diameter larger than that of the substrate W, and faces the held substrate W with a gap.

The chuck pin 12 is a holder that holds the substrate W with a gap from the lid unit 11a of the rotary table 11. The chuck pin 12 protrudes on the rotary table 11, and a plurality of chuck pins 12 is provided along positions corresponding to the outer peripheral edge of the substrate W at equal intervals. Further, the chuck pin 12 is provided to be movable by an opening/closing mechanism (not illustrated) between a closed position where the chuck pin 12 comes into contact with the outer peripheral edge of the substrate W to hold the substrate W, and an open position where the chuck pin 12 moves away from the outer peripheral edge of the substrate W to release the substrate W.

The drive unit 13 is a drive source (e.g., a motor) that rotates the rotary table 11. The drive unit 13 rotates the rotary table 11, thereby rotating the substrate W held by the chuck pin 12.

### (Processing Liquid Supply Unit)

As illustrated in FIG. 2, the processing liquid supply unit 20 supplies the processing liquid Lp to the substrate Wp that is rotating while being held by the rotary holding unit 10. The processing liquid supply unit 20 includes a first nozzle 21, a processing liquid supply pipe 22, a heater 23, and a valve 24. The first nozzle 21 is inserted through a support unit 62 to be described herein later and the cover body 63 in the heating unit 60, and is provided such that an ejection port 21a at the tip end thereof faces the vicinity of the center of the substrate W held by the rotary holding unit 10.

The first nozzle 21 is connected to a processing liquid supply source 25 such as a tank that stores the processing liquid Lp, via the processing liquid supply pipe 22. In the present embodiment, the processing liquid Lp that is supplied from the processing liquid supply source 25 is heated in advance. The heater 23 is provided in the middle of the processing liquid supply pipe 22. The processing liquid Lp supplied from the processing liquid supply source 25 passes through the processing liquid supply pipe 22, thereby being heated by the heater 23, and then, is ejected from the ejection port 21a of the first nozzle 21 toward the vicinity of the center of the substrate Wp.

The temperature of the processing liquid Lp ejected from the first nozzle 21 is, for example, 160° C. The valve 24 is provided in the middle of the processing liquid supply pipe 22. By opening and closing the valve 24, start and stop of the ejection of the processing liquid Lp from the first nozzle 21 are performed. The valve 24 is electrically connected to the control device 80 to be described herein later, and the opening and closing thereof are controlled by the control device 80.

### (Rinse Liquid Supply Unit)

As illustrated in FIG. 3, the rinse liquid supply unit 30 supplies the rinse liquid Lc to the substrate Wp held by the rotary holding unit 10. Further, as illustrated in FIG. 4, the rinse liquid supply unit 30 supplies the rinse liquid Lc to the substrate Wd held by the rotary holding unit 10. For example, pure water may be used as the rinse liquid Lc. The rinse liquid supply unit 30 includes a second nozzle 31, a rinse liquid supply pipe 32, and a valve 33. The second nozzle 31 is inserted through the support unit 62 to be described herein later, and the cover body 63 in the heating unit 60, and the ejection port 31a at the tip end thereof is provided to face the vicinity of the center of the substrate Wp or Wd held by the rotary holding unit 10.

The second nozzle 31 is connected to a rinse liquid supply source 34 such as a tank that stores the rinse liquid Lc, via the rinse liquid supply pipe 32. The rinse liquid Lc supplied from the rinse liquid supply source 34 passes through the rinse liquid supply pipe 32, and is ejected from the ejection port 31a of the second nozzle 31 toward the vicinity of the center of the substrate Wp or Wd. A valve 33 is provided in the middle of the rinse liquid supply pipe 32. By opening and closing the valve 33, start and stop of the ejection of the rinse liquid Lc from the second nozzle 31 are performed. The valve 33 is electrically connected to the control device 80 to be described herein later, and the opening and closing thereof are controlled by the control device 80.

### (Gas Supply Unit)

As illustrated in FIG. 5, the gas supply unit 40 supplies a gas to the space S formed between the substrate Wd held by the rotary holding unit 10 and the opposing surface 631 of the cover body 63. For example, nitrogen gas may be used as the gas. The gas supply unit 40 includes a gas supply pipe 41 and a valve 42. In FIG. 5, the distance between the opposing surface 631 of the cover body 63 and the dummy substrate Wd is enlarged for the convenience of description. However, the distance between the opposing surface 631 of the cover body 63 and the substrate Wd is the same as that in FIG. 4.

One end of the gas supply pipe 41 is connected to the rinse liquid supply pipe 32 of the rinse liquid supply unit 30, and the gas supply pipe 41 and the rinse liquid supply pipe 32 communicate with each other. That is, the gas that has passed through the gas supply pipe 41 flows through the rinse liquid supply pipe 32, and is supplied from the second nozzle 31 to the space S. That is, the second nozzle 31 may also be a part of the gas supply unit 40. By supplying the gas from the second nozzle 31 to the space S and blowing away the droplets d adhering to the opposing surface 631 of the cover body 63 toward a cup portion 51, the droplets d are removed.

The other end of the gas supply pipe 41 is connected to the gas supply source 43. A valve 42 is provided in the middle of the gas supply pipe 41. By opening and closing the valve 42, start and stop of the supply of the gas are performed. The valve 42 is electrically connected to the control device 80 to be described herein later, and the opening and closing thereof are controlled by the control device 80.

### (Liquid Receiving Unit)

The liquid receiving unit 50 is provided to surround the rotary holding unit 10, and receives the processing liquid Lp and the rinse liquid Lc scattered from the rotating substrate W. Further, the liquid receiving unit 50 receives the droplets d adhering to the opposing surface 631 of the cover body 63 during the second drying process to be described herein later. The liquid receiving unit 50 discharges the received processing liquid Lp, rinse liquid Lc, and droplets d to the outside of the substrate processing apparatus 1.

The liquid receiving unit 50 includes the cup portion 51 and a receiving portion 52. The cup portion 51 is a cylindrical body that covers the periphery of the rotary holding unit 10 with a gap therefrom, and is curved inward such that the upper diameter thereof decreases. The cup portion 51 is provided to be movable by a lifting mechanism (not illustrated) between a standby position where the cup portion 51 moves downward and waits such that the substrate Wp or Wd may be carried in and out (see, e.g., FIG. 1), and a processing position where the cup portion 51 moves upward to receive the processing liquid Lp, the rinse liquid Lc, and the droplets d scattered from the substrate W (see, e.g., FIGS. 2 to 5). The receiving portion 52 is an annular container provided below the cup portion 51 and opened at the upper side thereof.

The processing liquid Lp and the rinse liquid Lc scattered from the substrate W are received by the cup portion 51, and fall downward along the inner wall of the cup portion 51, thereby flowing into the receiving portion 52. Further, in the second drying process, the droplets d adhering to the opposing surface 631 are scattered outward by the gas supplied to the space S. The scattered droplets d are received by the cup portion 51, and fall downward along the inner wall of the cup portion 51, thereby flowing into the receiving portion 52. The processing liquid Lp, the rinse liquid Lc, and the droplets d that flow into the receiving portion 52 are discharged to the outside of the substrate processing apparatus 1 through a discharge port (not illustrated) formed in the bottom surface of the receiving portion 52.

### (Heating Unit)

The heating unit 60 irradiates the substrate W held by the rotary holding unit 10 with the light emitted from the light emitting element 61, thereby heating the substate W. By heating the substrate Wp, the heating unit 60 may heat the processing liquid Lp on the substrate Wp through heat conduction from the substrate Wp, and may maintain the processing liquid Lp on the substrate Wp at a high temperature. Further, the output of the heating unit 60 may be controlled not only to maintain the temperature of the processing liquid Lp, but also to further increase the temperature of the processing liquid Lp on the substrate Wp.

The heating unit 60 includes a plurality of light emitting elements 61 that irradiates light onto the held substrate W. The light emitting element 61 emits light (e.g., an electromagnetic wave) having a wavelength absorbed by the substrate W so as to heat the substrate W. The light emitted from the light emitting element 61 has a wavelength that is transmissive through the processing liquid Lp. Here, the description “absorbed by the substrate W” indicates that the light incident on the substrate W is absorbed to an extent sufficient to heat the substrate W, and includes not only a case where the light is completely absorbed by the substrate W, but also cases where a portion of the light is reflected on or transmitted through the substrate W. Further, the description “transmissive through the processing liquid Lp” indicates that the light incident on the processing liquid Lp is transmitted through the processing liquid Lp to an extent sufficient to heat the substrate Wp, and also includes cases where a portion of the light is absorbed by or reflected on the processing liquid Lp.

For example, an LED that emits light for heating is used as the light emitting element 61. The wavelength of the light emitted by the LED is, for example, 350 nm to 1,060 nm. More preferably, the central wavelength is 395 nm to 940 nm. In the present embodiment, an LED that emits light with a central wavelength of 395 nm is used. The output of the light emitting element 61 is controlled by the control device 80 to be described herein later.

Accordingly, even though the light from the light emitting element 61 is irradiated from above the space where the substrate W is held, that is, from above the processing liquid Lp supplied to the substrate Wp, the light is transmitted through the processing liquid Lp on the substrate Wp, and is absorbed by the substrate Wp, so that the substrate Wp may be heated. Further, the temperature of the processing liquid Lp increases by the heat conduction from the substrate Wp, so that an etching rate (e.g., a processing rate) increases.

The heating unit 60 includes the support unit 62, in addition to the light emitting element 61 described above. The support unit 62 is a member that supports the plurality of light emitting elements 61. The support unit 62 is a cylindrical member of which upper end is closed by a top plate 621. The diameter of the support unit 62 is equal to or greater than the diameter of the substrate W. The support unit 62 is disposed above the rotary table 11 at a position facing the lid unit 11a with a gap therefrom. Thus, the heating unit 60 is provided such that the light from the light emitting element 61 is irradiated from above the space in which the substrate W is held by the rotary holding unit 10. Further, two through holes 621a and 621b are formed in the vicinity of the center of the top plate 621 of the support unit 62.

The substrate processing apparatus 1 further includes the cover body 63. The cover body 63 is provided between the substrate W held by the rotary holding unit 10 and the heating unit 60 to cover the light emitting element 61. The heating unit 60 irradiates light onto the held substrate W through the cover body 63. The cover body 63 is a disk-shaped member that covers the end of the support unit 62 that faces the rotary table 11. That is, the cover body 63 is provided at the end of the support unit 62 opposite to the end thereof where the top plate 621 is provided. The cover body 63 is formed of a material that is resistant to the processing liquid Lp, and allows the light emitted from the light emitting element 61 to pass therethrough. That is, the cover body 63 is not directly heated even though light is emitted from the light emitting element 61. The cover body 63 is made of, for example, quartz. Further, two through holes 63a and 63b are formed in the vicinity of the center of the cover body 63.

As illustrated in FIG. 1, the first nozzle 21 is inserted through the through holes 621a and 63a such that the ejection port 21a at the tip end thereof is exposed from the cover body 63 to face the substrate W. The second nozzle 31 is inserted through the through holes 621b and 63b such that the ejection port 31a at the tip end thereof is exposed from the cover body 63 to face the substrate W. The cover body 63 includes the opposing surface 631 that faces the substrate W held by the rotary holding unit 10.

The plurality of light emitting elements 61 are attached to the support unit 62 to face the rotary table 11 with the cover body 63 interposed therebetween. The heating unit 60 includes a plurality of regions in which the light emitting elements 61 are arranged. That is, the plurality of light emitting elements 61 are divided into and arranged in a plurality of regions. In the present embodiment, the light emitting elements 61 are provided in regions corresponding to different positions in the radial direction of the substrate W, and the output of the light emitting elements 61 may be controlled for each region. Further, the plurality of light emitting elements 61 are arranged such that light may be irradiated over the entire processing target surface of the substrate W.

### (Lifting Mechanism)

As illustrated in FIG. 1, the lifting mechanism 70 supports the heating unit 60, and raises and lowers the heating unit 60 such that the opposing surface 631 of the cover body 63 approaches or separates from the substrate Wp or Wd. By raising and lowering the heating unit 60, the lifting mechanism 70 may raise and lower the cover body 63 provided in the support unit 62 of the heating unit 60. The lifting mechanism 70 includes an arm 71 and a column 72. The arm 71 is a member that extends in a direction parallel to the substrate W, and the outer peripheral portion of the support unit 62 is connected to one end of the arm 71. By supporting the support unit 62, the arm 71 may support the heating unit 60. The column 72 is provided in an upright state to extend in a direction perpendicular to the substrate W, and supports the other end of the arm 71. A drive source such as a ball screw mechanism or a cylinder (not illustrated) is provided in the column 72. The drive source raises and lowers the arm 71, so that the heating unit 60 may be raised and lowered.

The lifting mechanism 70 raises and lowers the heating unit 60, thereby positioning the opposing surface 631 of the cover body 63 at a height corresponding to any one of a carry-in/out position P1, a heating position P2, an approach position P3, and a rinse position P4. Each position is as follows.

Carry-in/out position P1: a height position spaced upward from the rotary table such that the hand of a transfer robot may be inserted when the substrate Wp or Wd is carried in and out (see, e.g., FIG. 1).

Heating position P2: a height position closer to the substrate Wp or Wd than the carry-in/out position P1 is, and a position at which the light emitting element 61 is not damaged by the radiant heat generated when the substrate Wp or Wd is heated (see, e.g., FIGS. 2 and 7); however, the opposing surface 631 of the cover body 63 does not come into contact with the processing liquid Lp on the substrate Wp.

Approach position P3: a position closer to the substrate Wp or Wd than the heating position P2 is, and a position at which the opposing surface 631 of the cover body can come into contact with the rinse liquid Lc on the substrate Wp or Wd (see, e.g., FIGS. 4 and 5).

Rinse position P4: a height position between the carry-in/out position P1 and the heating position P2, and a position when the rinse liquid Lc is supplied to the substrate Wp (see, e.g., FIG. 3).

The distance between the substrate W held by the rotary holding unit 10 and the opposing surface 631 of the cover body 63 located at the carry-in/out position P1 is an example of a first distance. The distance between the substrate W held by the rotary holding unit 10 and the opposing surface 631 of the cover body 63 located at the heating position P2 is an example of a second distance. The distance between the substrate W held by the rotary holding unit 10 and the opposing surface 631 of the cover body 63 located at the approach position P3 is an example of a third distance. The distance between the substrate W held by the rotary holding unit 10 and the opposing surface 631 of the cover body 63 located at the rinse position P4 is an example of a fourth distance.

### (Control Device)

The control device 80 controls each component of the substrate processing apparatus 1. In order to implement the various functions of the substrate processing apparatus 1, the control device 80 includes a processor that executes programs, a memory that stores various types of information such as programs and operation conditions, and a drive circuit that drives each element. That is, the control device 80 controls, for example, the rotary holding unit 10, the processing liquid supply unit 20, the rinse liquid supply unit 30, the gas supply unit 40, the liquid receiving unit 50, the heating unit 60, and the lifting mechanism 70.

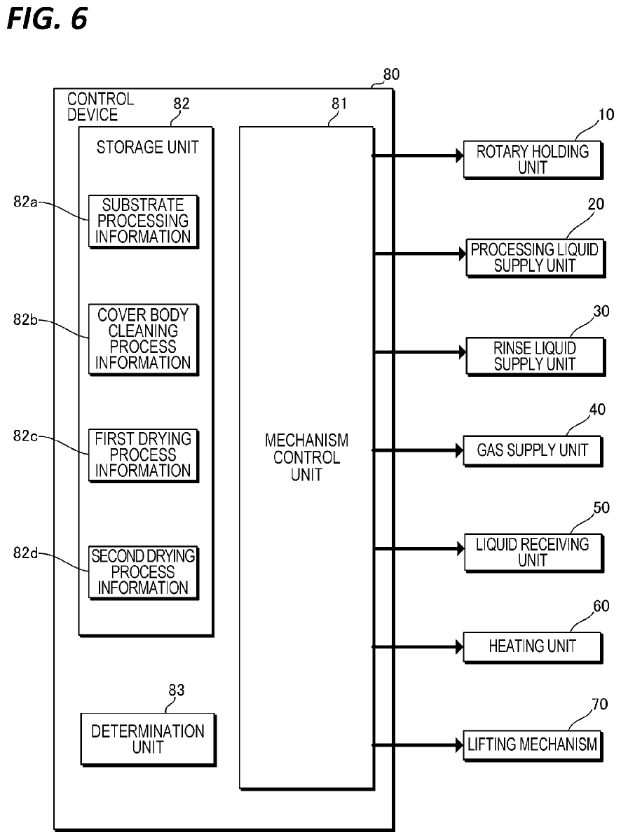

More specifically, as illustrated in FIG. 6, the control device 80 includes a mechanism control unit 81, a storage unit 82, and a determination unit 83. The mechanism control unit 81 controls, for example, the operations of the opening/closing mechanism of the rotary holding unit 10, the drive unit 13, the heater 23 and the valve 24 of the processing liquid supply unit 20, the valve 33 of the rinse liquid supply unit 30, the valve 42 of the gas supply unit 40, the lifting mechanism of the liquid receiving unit 50, the light emitting element 61 of the heating unit 60, and the drive source of the lifting mechanism 70, in accordance with the programs stored in the storage unit 82.

The storage unit 82 stores information such as programs and data for implementing the operation of each component that is controlled by the mechanism control unit 81. The storage unit 82 stores substrate processing information 82a, cover body cleaning process information 82b, first drying process information 82c, and second drying process information 82d. The substrate processing information 82a, the cover body cleaning process information 82b, the first drying process information 82c, and the second drying process information 82d are operation information on the components that are controlled by the mechanism control unit 81, in each process performed by the substrate processing apparatus 1.

The substrate processing information 82a is information for performing processing on the substrate Wp. The cover body cleaning process information 82b is information for performing a cover body cleaning process that cleans the opposing surface 631 of the cover body 63. The first drying process information 82c is information for performing the first drying process that heats the substrate Wd, thereby drying the opposing surface 631 of the cover body 63. The second drying process information 82d is information for performing the second drying process that supplies the gas to the space S between the substrate Wd and the opposing surface 631 of the cover body 63, thereby drying the opposing surface 631 of the cover body 63.

Further, the storage unit 82 stores a predetermined number of substrates Wp that are processed until the maintenance process of the cover body 63 is performed, as well as the number of processed substrates Wp that is counted by the determination unit 83. The maintenance process of the cover body 63 is a process that cleans and dries the opposing surface 631 of the cover body 63. In the present embodiment, the maintenance process of the cover body 63 includes the cover body cleaning process, the first drying process, and the second drying process.

The determination unit 83 counts the number of substrates Wp processed in the substrate processing apparatus 1. Further, the determination unit 83 determines whether the number of processed substrates Wp has reached a predetermined number.

When the determination unit 83 determines that the number of processed substrates Wp has reached the predetermined number, the maintenance process of the cover body 63 is performed. That is, the maintenance process of the cover body 63 is not performed every time a single substrate Wp is processed, but is performed after the predetermined number of substrates are processed. In the maintenance process of the cover body 63 according to the present embodiment, the dummy substrate Wd is used, instead of the substrate Wp that becomes a product.

When the determination unit 83 determines that the number of processed substrates Wp has reached the predetermined number, the maintenance process of the cover body 63 is started, and the determination unit 83 resets the number of substrates Wp that have been counted. Then, when a new substrate Wp is processed after the maintenance process of the cover body 63 is completed, the determination unit 83 starts the counting with the processed substrate Wp set as a first substrate.

### Operation

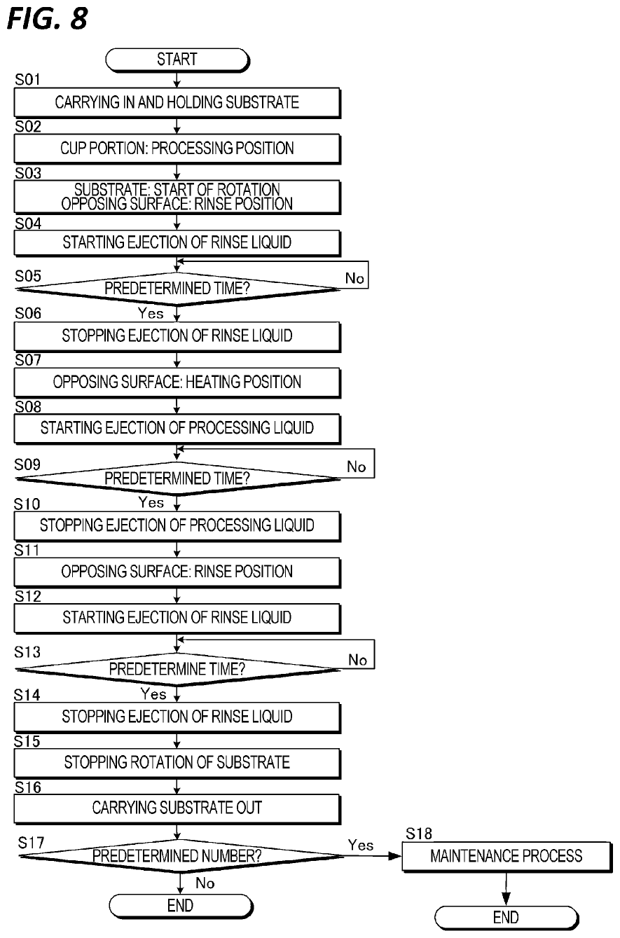

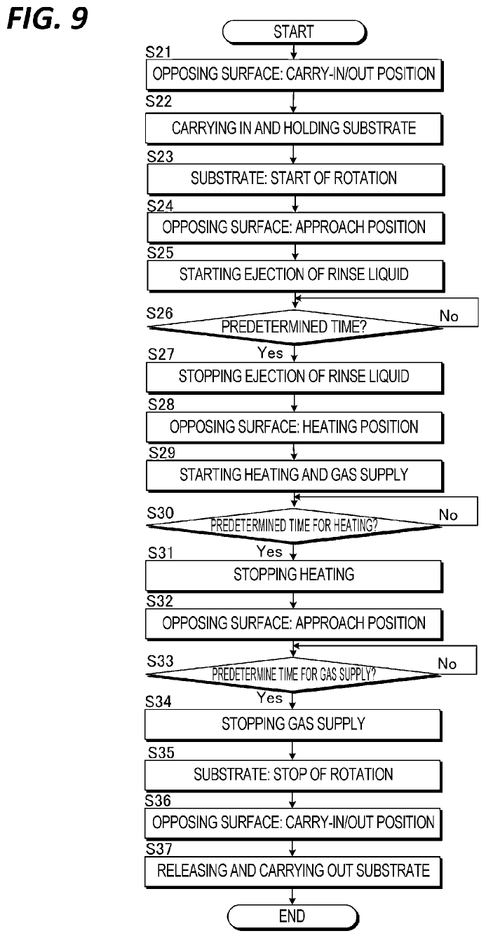

Next, descriptions will be made on the operation of the substrate processing apparatus 1 of the present embodiment that is controlled by the control device 80, with reference to the flowcharts in FIGS. 8 and 9, in addition to FIGS. 1 to 7. First, the processing performed on the substrate Wp based on the substrate processing information 82a will be described with reference to the flowchart in FIG. 8.

As illustrated in FIG. 1, the heating unit 60 is positioned in advance to make the opposing surface 631 of the cover body 63 located at the carry-in/out position P1, and the cup portion 51 is located at the standby position. The valve 24 of the processing liquid supply unit 20, the valve 33 of the rinse liquid supply unit 30, and the valve 42 of the gas supply unit 40 are closed.

In this state, the chuck pin 12 moves to the open position, and after the substrate Wp mounted on the hand of the transfer robot is carried in between the heating unit 60 and the rotary table 11, the chuck pin 12 moves to the closed position, so that the outer peripheral edge of the substrate Wp is supported by the chuck pin 12. As a result, the substrate Wp is held on the lid unit 11a of the rotary table 11 with a gap from the lid unit 11a (step S01). At this time, the substrate Wp is positioned such that the center thereof coincides with the rotation axis of the rotary table 11. Then, the cup portion 51 moves upward to be located at the processing position (step S02).

Subsequently, as illustrated in FIG. 3, the rotary table 11 rotates so that the substrate Wp held by the chuck pin 12 starts to rotate, and the heating unit 60 is lowered so that the opposing surface 631 of the cover body 63 is located at the rinse position P4 (step S03).

Then, a pre-rinse process is started. Specifically, the valve 33 of the rinse liquid supply unit 30 is opened, and the rinse liquid Lc is ejected from the second nozzle 31 toward the vicinity of the center of the substrate Wp (step S04). When the rinse liquid Lc is supplied to the rotating substrate Wp, the rinse liquid Lc sequentially moves toward the outer periphery of the substrate W, and spreads over the entire processing target surface of the substrate Wp.

Without the supply of the rinse liquid Lc, when the processing liquid Lp is supplied, the processing liquid Lp does not wet and spread over the entire processing target surface of the substrate Wp due to surface tension, which results in processing non-uniformity. In the present embodiment, in order to prevent the processing non-uniformity, the rinse liquid Lc is supplied until a predetermined time elapses (NO in step S05), before the processing liquid Lp is supplied. When the predetermined rinse time elapses (YES in step S05), the valve 33 of the rinse liquid supply unit 30 is closed, and the ejection of the rinse liquid Lc from the second nozzle 31 is stopped (step S06).

Next, as illustrated in FIG. 2, the heating unit 60 is lowered so that the opposing surface 631 of the cover body 63 is located at the heating position P2 (step S07). Then, the valve 24 of the processing liquid supply unit 20 is opened, and the processing liquid Lp is ejected from the first nozzle 21 toward the vicinity of the center of the substrate Wp (step S08). When the processing liquid Lp is supplied to the rotating substrate Wp, the processing liquid Lp sequentially moves toward the outer periphery of the substrate Wp, and spreads over the entire processing target surface of the substrate Wp. Since the rinse liquid Lc has been supplied to the processing target surface of the substrate Wp, the processing liquid Lp wets and spreads over the entire processing target surface of the substrate Wp, so that the processing non-uniformity is prevented.

With the start of the ejection of the processing liquid Lp, the heating of the substrate Wp by the light irradiation from the light emitting element 61 is started. The heating of the substrate Wp continues until a predetermined process time elapses, to perform an etching process (NO in step S09). During the etching process, the processing liquid Lp may splash and spread, and may adhere as the droplets d to the opposing surface 631 of the cover body 63.

When the predetermined process time elapses (YES in step S09), the valve 24 of the processing liquid supply unit 20 is closed, and the ejection of the processing liquid Lp from the first nozzle 21 is stopped (step S10). Simultaneously, the light irradiation from the light emitting element 61 is stopped.

As illustrated in FIG. 3, the heating unit 60 is raised so that the opposing surface 631 of the cover body 63 is located at the rinse position P4 (step S11). Then, the valve 33 of the rinse liquid supply unit 30 is opened, and the rinse liquid Lc is ejected from the second nozzle 31 toward the vicinity of the center of the substrate Wp (step S12). When the rinse liquid Lc is supplied to the rotating substrate Wp, the rinse liquid Lc sequentially moves toward the outer periphery of the substrate W, and spreads over the entire processing target surface of the substrate Wp. The rinse liquid supply unit 30 supplies the rinse liquid Lc until a predetermined time elapses (NO in step S13).

When the rinse liquid Lc is supplied to the processing liquid Lp that is the phosphoric acid solution, a large amount of water vapor is generated. At this time, since the opposing surface 631 of the cover body 63 is located at the rinse position P4, which is farther from the substrate Wp than the heating position P2 is, the adhesion of the water vapor to the opposing surface 631 of the cover body 63 may be suppressed. Further, since the rinse position P4 is closer to the substrate Wp than the carry in/out position P1 is, the liquid splashing caused by the supply of the rinse liquid Lc may be suppressed.

When the predetermined rinse time elapses (YES in step S13), the valve 33 of the rinse liquid supply unit 30 is closed, and the ejection of the rinse liquid Lc from the second nozzle 31 is stopped (step S14). The rotation of the rotary table 11 stops, so that the rotation of the substrate Wp held by the chuck pin 12 stops (step S15).

As illustrated in FIG. 1, the heating unit 60 is raised so that the opposing surface 631 of the cover body 63 is located at the carry-in/out position P1. Then, the cup portion 51 is lowered and located at the standby position. In this state, the hand of the transfer robot is inserted below the substrate Wp, and the chuck pin 12 moves to the open position so that the substrate Wp is placed on the hand of the transfer robot, and is carried out of the substrate processing apparatus 1 (step S16).

The determination unit 83 counts the number of processed substrates Wp. When the substrate Wp is carried out, the determination unit 83 counts the carried-out substrate Wp as a processed substrate Wp, and determines whether the number of processed substrates Wp has reached a predetermined number. When it is determined that the number of processed substrates Wp has not reached the predetermined number (NO in step S17), the maintenance process of the cover body 63 to be described herein later is not performed, and the processing is terminated. Thereafter, when the next substrate Wp is processed, the processing is performed starting from step S01 again. Meanwhile, when it is determined that the number of processed substrates Wp has reached the predetermined number (YES in step S17), the maintenance process of the cover body 63 is performed (step S18). After the maintenance process of the cover body 63 is performed, the process by the substrate processing apparatus 1 is terminated.

Next, the maintenance process of the cover body 63 (step S18) will be described in detail with reference to the flowchart of FIG. 9. In the substrate processing apparatus 1, as the maintenance process of the cover body 63, the cover body cleaning process, the first drying process, and the second drying process are performed. The cover body cleaning process is performed based on the cover body cleaning process information 82b, the first drying process is performed based on the first drying process information 82c, and the second drying process is performed based on the second drying process information 82d. As described above, the maintenance process of the cover body 63 is performed every time the number of processed substrates Wp reaches the predetermined number.

When the maintenance process of the cover body 63 is started, the opposing surface 631 of the cover body 63 is located at the carry-in/out position P1 (step S21). The cup portion 51 is located at the standby position. In the maintenance process of the cover body 63, the dummy substrate Wd, which is different from the substrate Wp that becomes a product, is used. Thus, the substrate Wd mounted on the hand of the transfer robot is carried in and held by the chuck pin 12 (step S22)

As the rotary table 11 rotates, the rotation of the substrate Wd held by the chuck pin 12 starts (step S23). At this time, the cup portion 51 is raised and located at the processing position.

When the substrate Wd is held and starts to rotate, the cover body cleaning process starts. Specifically, the heating unit 60 is lowered, and the opposing surface 631 of the cover body 63 is located at the approach position P3 (step S24). The rotation of the substrate Wd may be started after the opposing surface 631 of the cover body 63 is located at the approach position P3, or while the heating unit 60 is being moved. Then, the valve 33 of the rinse liquid supply unit 30 is opened, and the rinse liquid Lc is ejected from the second nozzle 31 to the vicinity of the center of the substrate Wd (step S25). When the rinse liquid Lc is supplied to the rotating substrate Wd, the rinse liquid Lc sequentially moves toward the outer periphery of the substrate Wd, and spreads over the entire processing target surface of the substrate Wp, thereby forming a liquid film of the rinse liquid Lc. Since the opposing surface 631 of the cover body 63 is located at the approach position P3, the opposing surface 631 comes into contact with the liquid film of the rinse liquid Lc on the substrate Wd, as illustrated in FIG. 4. Consequently, the droplets d that have adhered to the opposing surface 631, containing the processing liquid Lp, are washed away together with the rinse liquid Lc, so that the opposing surface 631 of the cover body 63 may be cleaned.

The supply of the rinse liquid Lc is performed until a predetermined time elapses (NO in step S26). When the predetermined time elapses (YES in step S26), the valve 33 of the rinse liquid supply unit 30 is closed, and the ejection of the rinse liquid Lc from the second nozzle 31 is stopped (step S27). As a result, the cover body cleaning process is terminated.

Next, the first drying process and the second drying process are performed. First, as illustrated in FIG. 7, the heating unit 60 is raised so that the opposing surface 631 of the cover body 63 is located at the heating position P2 (step S28). Then, the heating of the substrate Wd is started, and simultaneously, the gas supply is started (step S29). That is, the first drying process and the second drying process are started simultaneously. Specifically, in the first drying process, light is irradiated from the light emitting element 61 of the heating unit 60 onto the substrate Wd, to heat the substrate Wd. The opposing surface 631 of the cover body 63 is heated by the radiant heat from the heated substrate Wd. Accordingly, the droplets d adhering to the opposing surface 631 of the cover body 63 are heated and removed from the opposing surface 631, or become small.

Further, in the second drying process, a gas is supplied to the space S between the opposing surface 631 of the cover body 63 and the substrate Wd. Simultaneously with the start of light irradiation from the light emitting element 61, the valve 42 of the gas supply unit 40 is opened, and a gas is supplied from the second nozzle 31 to the space S between the opposing surface 631 of the cover body 63 and the substrate Wd. The droplets d adhering to the opposing surface 631 of the cover body 63 are blown away by the gas, so that the opposing surface 631 is dried. Further, since the ejection port 31a of the second nozzle 31 that ejects the gas faces the vicinity of the center of the rotating substrate Wd, the gas supplied to the space S flows from the center toward the outer side where the cup portion 51 is disposed. Accordingly, the droplets d are blown toward the cup portion 51 by the gas.

Here, since the heating of the substrate Wd and the gas supply are started simultaneously, the first drying process and the second drying process are performed in parallel for at least part of a period. By performing the first drying process and the second drying process in parallel, the gas in the space S is also heated by the radiant heat from the substrate Wd, and the droplets d adhering to the opposing surface 631 are heated by the heated gas. Accordingly, the heating of the droplets d adhering to the opposing surface 631 is accelerated, which reduces the time for drying the opposing surface 631 of the cover body 63.

The heating by the heating unit 60 is performed until a predetermined time elapses (NO in step S30). When the predetermined time elapses (YES in step S30), the light irradiation by the light emitting element 61 is stopped, and the heating of the substrate Wd is stopped (step S31).

In this way, the first drying process is terminated. At the stage when the heating is stopped, the gas supply is not stopped. That is, the second drying process continues even after the first drying process is terminated. At the stage when the first drying process is terminated, the droplets d adhering to the opposing surface 631 of the cover body 63 are smaller than those before the first drying process is started. Alternatively, the droplets d adhering to the opposing surface 631 of the cover body 63 are removed by the heating and the gas supply.

When the heating of the substrate Wd is stopped, as illustrated in FIG. 5, the heating unit 60 is lowered by the lifting mechanism 70, so that the opposing surface 631 of the cover body 63 is located at the approach position P3 (step S32). That is, the space S between the opposing surface 631 of the cover body 63 and the substrate Wd becomes narrower than when the substrate Wd is heated. Thus, the flow velocity of the gas ejected from the second nozzle 31 to the space S and flowing toward the outer side increases, as compared to when the opposing surface 631 is located at the heating position P2. Accordingly, the droplets d adhering to the opposing surface 631 are readily blown away. Further, as a result of the heating of the droplets d in the first drying process, the droplets d become small. Consequently, the droplets d adhering to the opposing surface 631 are easily blown away. By supplying the gas with the increased flow velocity to the opposing surface 631 of the cover body 63 to which the droplets d that have become small in the first drying process adhere, the droplets d may be efficiently removed. The droplets d blown away from the opposing surface 631 are received in the cup portion 51.

The gas supply is performed until a predetermined time elapses (NO in step S33). When the predetermined time elapses after the start of the gas supply (YES in step S33), the valve 42 of the gas supply unit 40 is closed, and the gas supply is stopped (step S34). In this way, the second drying process is terminated. In the present embodiment, the time from the start to the stop of the gas supply is longer than the time from the start to the stop of the heating of the substrate Wd. Thus, after the first drying process and the second drying process are performed in parallel, the second drying process is performed alone.

When the second drying process is terminated, the rotation of the rotary table 11 stops, so that the rotation of the substrate Wd stops (step S35). Thereafter, the cup portion 51 is lowered and located at the standby position. Then, the heating unit 60 is raised, and the opposing surface 631 of the cover body 63 is located at the carry-in/out position P1 (step S36). The rotation of the substrate Wd may stop after the movement to the carry-in/out position P1, or during the movement from the approach position P3 toward the carry-in/out position P1. In the state where the heating unit 60 is moved to make the opposing surface 631 of the cover body 63 to be located at the carry-in/out position P1, and the cup portion 51 is located at the standby position, the hand of the transfer robot is inserted below the substrate Wd, and the chuck pin 12 moves to the open position so that the substrate Wd is placed on the hand of the transfer robot, and is carried out of the substrate processing apparatus 1 (step S37).

### Effects

(1) The substrate processing apparatus 1 of the present embodiment includes: the rotary holding unit 10 that holds and rotates the substrate W; the processing liquid supply unit 20 that supplies the processing liquid Lp to the substrate Wp that is rotating while being held by the rotary holding unit 10; the heating unit 60 that irradiates light onto the substrate Wp or Wd held by the rotary holding unit 10, thereby heating the substrate Wp or Wd; the cover body 63 including the opposing surface 631 that faces the substrate Wp or Wd held by the rotary holding unit 10, provided between the held substrate Wp or Wd and the heating unit 60, and transmitting the light irradiated by the heating unit 60; and the control device 80 that controls the rotary holding unit 10, the processing liquid supply unit 20, and the heating unit 60. The control device 80 performs a control to supply the processing liquid Lp to the substrate Wp that is rotating by the rotary holding unit 10, thereby processing the substrate Wp, and to perform a first drying process that irradiates light onto the substrate Wd held by the rotary holding unit 10 to heat the substrate Wd, thereby drying the opposing surface 631 of the cover body 63.

Further, a substrate processing method of the present embodiment includes: holding and rotating the substrate Wp or Wd; supplying the processing liquid Lp to the rotating substrate Wp, thereby processing the substrate Wp; and drying the cover body 63 provided between the held substrate Wd and the heating unit 60 that heats the substrate Wd by irradiating light onto the held substrate Wd. The cover body 63 transmits the light irradiated by the heating unit 60, and in the drying the cover body 63, the heating unit 60 irradiates light onto the substrate Wd to heat the substrate Wd, thereby drying the opposing surface 631 of the cover body 63 that faces the substrate Wd held by the rotary holding unit 10.

As a comparative example for substrate processing by heating, in a case where a substrate is processed by heating a processing liquid on the substrate through a cover body using a heating unit including a heater or the like covered by the cover body, even when droplets adhere to the opposing surface of the cover body during the substrate processing, the cover body itself is also heated and reaches a high temperature, and therefore, the droplets evaporate and are removed after the substrate processing is terminated.

Meanwhile, in the present embodiment, the heating unit 60 includes the light emitting element 61, and heats the substrate Wp by light to process the substrate Wp. Since the light emitted by the light emitting element 61 passes through the cover body 63, the cover body 63 is not heated and does not reach a high temperature when the substrate Wp is heated by irradiating light thereonto. Thus, the droplets d that have adhered to the opposing surface 631 of the cover body 63 during the processing on the substrate Wp are not removed and remain. Thus, independently of the processing on the substrate Wp, the first drying process is performed using the substrate Wd as the maintenance process of the cover body 63. In the first drying process, the substrate Wd is heated, and the opposing surface 631 of the cover body 63 is heated using the radiant heat from the heated substrate Wd. As a result, the droplets d adhering to the opposing surface 631 of the cover body 63 may be heated and removed. Therefore, during the processing on the substrate Wp, the droplets d adhering to the opposing surface 631 of the cover body 63 may be suppressed from falling onto the substrate Wp and contaminating the substrate Wp.
(2) The control device 80 is configured to supply the processing liquid Lp to the first substrate Wp, thereby processing the first substrate Wp, and perform the first drying process that irradiates light onto the second substrate Wd to heat the second substrate Wd, thereby drying the opposing surface 631 of the cover body 63.
(3) The first substrate Wp is a substrate that becomes a product, and the second substrate Wd is a dummy substrate.

Since the first drying process is performed using the substrate Wd different from the substrate Wp that is processed with the processing liquid Lp, the opposing surface 631 of the cover body 63 may be dried without contaminating the substrate Wp subjected to the processing with the processing liquid Lp.
(4) The substrate processing apparatus of the present embodiment further includes the lifting mechanism 70 that moves the cover body 63 to change the distance between the substrate W held by the rotary holding unit 10 and the opposing surface 631 of the cover body 63. The control device 80 performs a control to perform the first drying process in the state where the distance between the substrate Wd held by the rotary holding unit 10 and the opposing surface 631 of the cover body 63 is a second distance shorter than a first distance that is a distance when the substrate Wd is carried in.

Accordingly, the first drying process may be performed in the state where the substrate Wd and the cover body 63 are close to each other, and the radiant heat from the substrate Wd may be efficiently transferred to the opposing surface 631 of the cover body 63. As a result, the droplets d adhering to the opposing surface 631 of the cover body 63 may be efficiently removed.
(5) The substrate processing apparatus of the present embodiment further includes: the rinse liquid supply unit 30 that supplies the rinse liquid to the substrate Wd; and the lifting mechanism 70 that moves the cover body 63 to change the distance between the substrate W held by the rotary holding unit 10 and the opposing surface 631 of the cover body 63. The control device 80 performs a control to perform the cover body cleaning process that moves the cover body 63 and brings the opposing surface 631 of the cover body 63 into contact with the rinse liquid Lc supplied to the substrate Wd by the rinse liquid supply unit 30, thereby cleaning the cover body 63, and the cover body cleaning process is performed prior to the first drying process.

In this way, in the maintenance process of the cover body 63, the cover body cleaning process is performed prior to the first drying process, so that the droplets d adhering to the opposing surface 631 of the cover body 63 may be washed away by the rinse liquid Lc. Therefore, since the opposing surface of the cover body 63 may be dried after the processing liquid Lp, particles or the like contained in the droplets d are washed away, the opposing surface 631 of the cover body 63 may be maintained to be clean.
(6) The substrate processing apparatus of the present embodiment further includes the gas supply unit 40 that supplies a gas to the space S formed between the substrate Wd and the opposing surface 631 of the cover body 63, and the control device 80 performs a control to perform a second drying process that supplies the gas to the space S formed between the substrate Wd and the opposing surface 631, thereby drying the opposing surface 631.

By the gas supplied to the space S, the droplets d adhering to the opposing surface 631 of the cover body 63 are blown to the outer side, so that the droplets d of the opposing surface 631 may be removed. That is, since not only the drying by the heating in the first drying process, but also the drying by the gas supply in the second drying process are performed, the droplets d may be removed efficiently.
(7) The second drying process is started simultaneously with or after the start of the first drying process. Through the drying by the heating in the first drying process, the droplets d become small and are readily blown away. Thus, by performing the drying by the gas supply in the second drying process on the droplets d that are being subjected to or have undergone the drying by the heating in the first drying process, the droplets d may be blown toward the cup portion 51 in a short time, so that the process efficiency may be improved.
(8) The substrate processing apparatus of the present embodiment further includes the gas supply unit 40 that supplies a gas to the space S formed between the substrate Wd and the opposing surface 631 of the cover body 63, and the control device 80 performs a control to perform the second drying process that supplies the gas to the space S formed between the substrate Wd and the opposing surface 631 in the state where the distance between the substrate W held by the rotary holding unit 10 and the opposing surface 631 of the cover body 63 is a third distance shorter than the second distance, thereby drying the opposing surface 631.

In this way, by performing the second drying process in the state where the substrate W and the opposing surface 631 of the cover body 63 are closer to each other than when the substrate W is heated, the flow velocity of the supplied gas increases, enhancing the force to blow away the droplets d, so that the droplets d adhering to the opposing surface 631 of the cover body 63 may be efficiently blown toward the cup portion 51, and removed.

Further, when the first drying process is performed in the state of the second distance, damage to, for example, the light emitting element 61 may be suppressed. In the first drying process, peripheral members such as the light emitting element 61 and the support unit 62 are also heated by the radiant heat from the heated substrate Wd. When the radiant heat is high, for example, the light emitting element 61 may be damaged. Thus, it is advantageous to perform the first drying process in the state where the distance between the substrate Wd held by the rotary holding unit 10 and the opposing surface 631 of the cover body 63 is the second distance longer than the third distance.
(9) The first drying process and the second drying process are performed in parallel for at least a part of a period.

In the period when the first drying process and the second drying process are performed in parallel, the gas supplied to the space S is heated by the radiant heat from the heated substrate Wd. The heated gas may accelerate the heating of the droplets d adhering to the opposing surface 631, so that the time for drying the opposing surface 631 may be reduced.

### Modifications

In the embodiment described above, the lifting mechanism 70 raises and lowers the heating unit 60. However, the present disclosure is not limited thereto as long as the distance between the substrate W and the opposing surface 631 of the cover body 63 may be changed. For example, the lifting mechanism 70 may raise and lower the rotary table 11 in the state where the chuck pin 12 holds the substrate W, so as to raise and lower the substrate W. Further, the lifting mechanism 70 may raise and lower both the substrate W and the heating unit 60. The lifting mechanism 70 may be any mechanism that is capable of moving at least one of the substrate W held by the rotary holding unit 10 and the cover body 63, thereby changing the distance between the substrate W held by the rotary holding unit 10 and the cover body 63.
(2) The height of the opposing surface 631 of the cover body 63 in each process is not limited to the positions P1 to P4 described above. For example, as long as the opposing surface 631 of the cover body 63 may be dried, the second drying process may be performed in the state where the opposing surface 631 of the cover body 63 is located between the heating position P2 and the approach position P3. Further, the carry-in/out position P1 and the rinse position P4 may be at the same height.

As long as the opposing surface 631 of the cover body 63 may be dried in the first drying process, the heating position P2 may be at the same height as the carry-in/out position P1 or the rinse position P4, or may be located between the carry-in/out position P1 and the rinse position P4. Further, the heating position P2 may be at the same height as the approach position P3. When the height of the heating position P2 is changed as described above, the output of the light emitting element 61 is changed such that the substrate Wp or Wd may be efficiently heated without damaging the light emitting element 61 by the radiant heat generated when the substrate Wp or Wd is heated. Further, as long as the output of the light emitting element 61 may be changed to prevent the damage to the light emitting element 61, the heating position P2 when the substrate Wp is heated during the processing on the substrate Wp and the heating position P2 when the substrate Wd is heated during the first drying process may be different from each other.
(3) The cover body cleaning process may be omitted. Further, the second drying process may be omitted. When the second drying process is omitted, the time for performing the first drying process may be extended, so that the droplets d adhering to the opposing surface 631 of the cover body 63 may be removed.
(4) In the cover body cleaning process, the substrate Wp that becomes a product may be used, instead of the dummy substrate Wd. That is, while supplying the rinse liquid Lc to the substrate Wp that becomes a product, the opposing surface 631 of the cover body 63 may be located at the approach position P3, and while performing the rinse process on the substrate Wp, the cover body cleaning process may be performed simultaneously and in parallel. In this case, when the determination unit 83 determines that the number of processed substrates Wp has reached the predetermined number, the cover body cleaning process is performed in parallel with the rinse process on the substrate Wp to be processed at the next time. Then, after the substrate Wp is carried out, the dummy substrate Wd is carried in, and the first drying process and the second drying process are performed. As a result, the efficiency of the maintenance process of the cover body 63 is improved, as compared to the case where the cover body cleaning process is performed using the dummy substrate Wd.
(5) In the embodiment described above, the second drying process is started simultaneously with the start of the first drying process. However, the second drying process may not be started simultaneously with the start of the first drying process, as long as the droplets d adhering to the opposing surface 631 may be removed, and the opposing surface 631 may be dried. For example, the second drying process may be started after the start of the first drying process. That is, the first drying process may be started, and the second drying process may be started during the first drying process. Further, the embodiment described above includes the state where the first drying process and the second drying process are performed in parallel. However, the state where the first drying process and the second drying process are performed in parallel may not be included. For example, the second drying process may be started after the first drying process is terminated. In this case, the first drying process may be performed in the state where the opposing surface 631 is located at the heating position P2, and the second drying process may be performed after the opposing surface 631 is moved to the approach position P3.

Further, the second drying process is terminated after the termination of the first drying process. However, the second drying process may be terminated before or simultaneously with the termination of the first drying process, as long as the droplets d adhering to the opposing surface 631 may be removed, and the opposing surface 631 may be dried.
(6) The gas supply unit 40 may supply the gas from the outer side of the opposing surface 631 of the cover body 63 to the space S between the opposing surface 631 of the cover body 63 and the substrate Wd, thereby blowing away and removing the droplets d adhering to the opposing surface 631. In this case, the height of the opposing surface 631 of the cover body 63 during the second drying process is not limited to the approach position P3.
(7) In the embodiment described above, the gas supply pipe 41 of the gas supply unit 40 is connected to the rinse liquid supply pipe 32. However, the gas supply pipe 41 may be connected to the processing liquid supply pipe 22 of the processing liquid supply unit 20, and the gas may be ejected from the first nozzle 21. Here, when the gas is ejected, the processing liquid Lp remaining in the processing liquid supply pipe 22 may be ejected together with the gas passing through the processing liquid supply pipe 22, and may adhere to the opposing surface 631. Thus, as in the embodiment described above, it is advantageous to connect the gas supply pipe 41 to the rinse liquid supply pipe 32 through which the rinse liquid Lc, which has less influence even though adhering to the opposing surface 631, flows, such that the gas is ejected from the second nozzle 31. Further, the gas supply unit 40 may further include a third nozzle that is connected to the gas supply pipe 41 and ejects the gas, separately from the first nozzle 21 and the second nozzle 31. In this case, the third nozzle of the gas supply unit 40 is inserted through the support unit 62 and the cover body 63, and is provided such that the ejection port thereof faces the vicinity of the center of the substrate W held by the rotary holding unit 10.
(8) The substrate processing apparatus 1 may include a liquid detection unit that detects the droplets d adhering to the opposing surface 631 of the cover body 63. The liquid detection unit is, for example, a camera that captures images of the opposing surface 631 of the cover body 63. The control device 80 determines whether a result detected by the liquid detection unit exceeds a threshold value. The threshold value may be set based on whether the adhesion of droplets d occurs, or based on a predetermined amount that is considered to indicate a large amount of adhered droplets d. Then, when the determination unit 83 determines that the droplets d have adhered to the opposing surface 631, the maintenance process of the cover body 63 is performed. As a result, the maintenance process may be performed only when the maintenance process of the cover body 63 is necessary, so that the process efficiency is improved.
(9) In the embodiment described above, the maintenance process of the cover body 63 is performed every time the number of processed substrates Wp reaches the predetermined number. However, the predetermined number may refer to a plurality of substrates or a single substrate. That is, the maintenance process of the cover body 63 may be performed each time a single substrate Wp is processed.
(10) The processing performed by the substrate processing apparatus 1 is not limited to the etching process. Any processing may be performed, which processes the substrate Wp by supplying the processing liquid Lp while heating the substrate Wp. For example, a resist film removal process may be performed, which removes a resist film formed on the processing target surface of the substrate Wp.
(11) A thermometer may be provided to measure the temperature of the substrate Wd, and in the first drying process, the heating unit 60 may be controlled such that the substrate Wd reaches a temperature necessary for drying the opposing surface 631. Then, when a predetermined time elapses after the substrate Wd reaches the temperature necessary for drying the opposing surface 631, the heating by the heating unit 60 may be stopped. As a result, the first drying process may be performed at an appropriate temperature for an appropriate time, and the drying of the opposing surface 631 may be performed efficiently.
(12) The rinse liquid Lc supplied during the cover body cleaning process may be heated to a temperature higher than room temperature. In this case, a heating mechanism may be provided in the middle of the rinse liquid supply pipe 32. As a result, the opposing surface 631 may be heated in advance before the first drying process for heating the opposing surface 631 is performed. Further, the gas supplied during the second drying process may be heated to a high temperature. In this case, a heating mechanism may be provided in the middle of the gas supply pipe 41. As a result, the efficiency in drying the opposing surface 631 may be improved.

The dummy substrate Wd may not be a silicon wafer. The dummy substrate Wd may be made of any material that may absorb the light irradiated by the light emitting element 61 and generate the radiating heat. Further, the dummy substrate Wd may not have the same diameter as the substrate Wp that becomes a product, as long as the rotary holding unit 10 may hold the dummy substrate Wd, and the opposing surface 631 may be dried.

### Other Embodiments

While the embodiment of the present disclosure has been described, the embodiment is merely illustrative, and is not intended to limit the scope of the invention. The embodiment described above may be implemented in various other forms, and various omissions, substitutions, and modifications may be made without departing from the scope of the invention. The embodiment and modifications thereof are included in the scope or gist of the invention, and are also included in the scope equivalent to the invention described in the claims.

What is claimed is:

1. A substrate processing apparatus comprising:
a rotary holder configured to hold and rotate a substrate;
a processing liquid supply configured to supply a processing liquid to the substrate that is rotating while being held by the rotary holder;
a heater configured to irradiate light onto the substrate held by the rotary holder, thereby heating the substrate;
a cover body including an opposing surface that faces the substrate held by the rotary holder, provided between the substrate held by the rotary holder and the heater, and transmitting the light irradiated by the heater; and
a controller configured to control the rotary holder, the processing liquid supply, and the heater,
wherein the controller is configured to:
supply the processing liquid to the substrate that is rotating by the rotary holder, thereby processing the substrate, and
perform a first drying process that irradiates the light onto the substrate held by the rotary holder to heat the substrate, thereby drying the opposing surface of the cover body.

2. The substrate processing apparatus according to claim 1, wherein
the controller is configured to
supply the processing liquid to a first substrate held by the rotary holder, thereby processing the first substrate, and
perform the first drying process that irradiates the light onto a second substrate different from the first substrate and held by the rotary holder to heat the second substrate, thereby drying the opposing surface of the cover body.

3. The substrate processing apparatus of claim 2, wherein
the first substrate is a substrate that becomes a product, and
the second substrate is a dummy substrate.

4. The substrate processing apparatus according to claim 1, further comprising:
a lift configured to move at least one of the substrate held by the rotary holder and the cover body to change a distance between the substrate held by the rotary holder and the opposing surface of the cover body,
wherein the controller is configured to perform the first drying process in a state where the distance between the substrate held by the rotary holder and the opposing surface of the cover body is a second distance shorter than a first distance that is a distance when the substrate is carried in.

5. The substrate processing apparatus according to claim 1, further comprising:
a rinse liquid supply configured to supply a rinse liquid to the substrate; and
a lift configured to move at least one of the substrate held by the rotary holder and the cover body to change a distance between the substrate held by the rotary holder and the opposing surface of the cover body,
wherein the controller is configured to perform a cover body cleaning process that moves at least one of the substrate held by the rotary holder and the cover body and brings the opposing surface of the cover body into contact with the rinse liquid supplied to the substrate by the rinse liquid supply, thereby cleaning the opposing surface, and
the cover body cleaning process is performed prior to the first drying process.

6. The substrate processing apparatus according to claim 1, further comprising:
a gas supply configured to supply a gas into a space formed between the substrate and the opposing surface of the cover body,
wherein the controller is configured to perform a second drying process that supplies the gas to the space formed between the substrate and the opposing surface of the cover body, thereby drying the opposing surface.

7. The substrate processing apparatus according to claim 6, wherein the second drying process is started simultaneously with or after start of the first drying process.

8. The substrate processing apparatus according to claim 4, further comprising:
a gas supply configured to supply a gas into a space formed between the substrate and the opposing surface of the cover body,
wherein the controller is configured to perform a second drying process that supplies the gas to the space formed between the substrate and the opposing surface of the cover body in a state where the distance between the substrate held by the rotary holder and the opposing surface of the cover body is a third distance shorter than the second distance, thereby drying the opposing surface.

9. The substrate processing apparatus according to claim 6, wherein the first drying process and the second drying process are performed in parallel for at least a portion of a period.

10. The substrate processing apparatus of claim 1, further comprising:
a liquid detector configured to detect droplets adhering to the opposing surface of the cover body,
wherein the controller is configured to perform the first drying process when a result detected by the liquid detector exceeds a threshold value.

11. A substrate processing method, comprising:
holding and rotating a substrate by a rotary holder;
supplying a processing liquid to the rotating substrate, thereby processing the substrate; and
drying a cover body provided between the substrate held by the rotary holder and a heater configured to heat the substrate by irradiating light onto the substrate,
wherein the cover body transmits the light irradiated by the heater, and
in the drying the cover body, the heater irradiates the light onto the substrate to heat the substrate, thereby drying the opposing surface of the cover body that faces the substrate held by a rotary holder.
